(19) United States
(12) Patent Application Publication
(10) Pub. No.: US 2023/0207999 A1
(43) Pub. Date: Jun. 29, 2023

(54) MULTILAYER SUBSTRATE, ANTENNA MODULE, FILTER, COMMUNICATION DEVICE, TRANSMISSION LINE, AND MULTILAYER SUBSTRATE MANUFACTURING METHOD

(71) Applicant: Murata Manufacturing Co., Ltd., Nagaokakyo-shi (JP)

(72) Inventors: Kohei HARATANI, Nagaokakyo-shi (JP); Kengo ONAKA, Nagaokakyo-shi (JP); Hirotsugu MORI, Nagaokakyo-shi (JP)

(73) Assignee: Murata Manufacturing Co., Ltd., Nagaokakyo-shi (JP)

(21) Appl. No.: 18/171,401

(22) Filed: Feb. 20, 2023

Related U.S. Application Data
(63) Continuation of application No. PCT/JP2021/026263, filed on Jul. 13, 2021.

(30) Foreign Application Priority Data
Aug. 21, 2020 (JP) 2020-140199

(51) Int. Cl. H01P 1/20; H01Q 1/12; H01P 3/08

(52) U.S. Cl. CPC H01P 1/20; H01P 3/08; H01Q 1/12

(57) ABSTRACT

A multilayer substrate in which dielectric layers are laminated, the multilayer substrate including: a first electrode formed on the dielectric layers; and a first ground electrode disposed so as to be opposite to the first electrode in a multilayer direction. In the multilayer substrate, a plurality of dielectric layers include a first layer and a second layer that are disposed between a layer in which the first electrode is formed and a layer in which the first ground electrode is formed. In the first layer, a filler having permittivity lower than permittivity of a base material forming the dielectric layer is not disposed. In the second layer, the filler is disposed in at least a part of a region where the first electrode and the first ground electrode overlap each other in planar view of the multilayer substrate from the multilayer direction.

### CROSS-REFERENCE TO RELATED APPLICATIONS

The present application is a continuation of PCT/JP2021/026263, filed Jul. 13, 2021, which claims priority to JP 2020-140199, filed in Japan on Aug. 21, 2020, and the entire contents of both are hereby incorporated by reference in their entirety.

### TECHNICAL FIELD

The present disclosure relates to a multilayer substrate, an antenna module, a filter, a communication device, a transmission line, and a multilayer substrate manufacturing method, and more specifically, relates to a technique for reducing an effective permittivity in a dielectric included in the multilayer substrate in a device such as an antenna including the dielectric substrate, and preventing a size and improving a characteristic of the device such as the antenna including the dielectric substrate.

### BACKGROUND

Conventionally, a dielectric substrate in which a filler having a hollow structure is dispersed and mixed. In conventional processes, an effective permittivity of a dielectric substrate is reduced by dispersedly disposing the filler having the hollow structure in the dielectric substrate, and a transmission loss is reduced when the dielectric substrate is used as a transmission line.

### SUMMARY

In an exemplary implementation of the present application, a multilayer substrate comprises: a plurality of dielectric layers; a first electrode disposed on the plurality of dielectric layers; and a first ground electrode disposed on the plurality of dielectric layers and disposed so as to be opposite to the first electrode in a multilayer direction, wherein the plurality of dielectric layers include a first layer and a second layer disposed between the first electrode and the first ground electrode, a filler, having a permittivity lower than a permittivity of a base material of the plurality of dielectric layers, is disposed in the second layer and is not disposed in the first layer, and in the second layer, the filler is disposed in at least a part of a region where the first electrode and the first ground electrode overlap each other in a planar view of the multilayer substrate from the multilayer direction.

### BRIEF DESCRIPTION OF DRAWINGS

FIG. 1 is a block diagram illustrating an example of a communication device to which an antenna module formed using a multilayer substrate according to a first embodiment is applied.

FIG. 2 is a sectional view of the antenna module of the first embodiment.

FIG. 3 is a simulation result in which antenna characteristics between the antenna module of the first embodiment and an antenna module without a filler (comparative example) are compared.

FIG. 4 is a view illustrating an example of a manufacturing process of the antenna module in FIG. 2.

FIG. 5 is a sectional view illustrating an antenna module of a first modification.

FIG. 6 is a sectional view illustrating an antenna module of a second modification.

FIG. 7 is a sectional view illustrating an antenna module of a third modification.

FIG. 8 is a sectional view illustrating an antenna module of a fourth modification.

FIG. 9 is a sectional view illustrating an antenna module of a fifth modification.

FIG. 10 is a sectional view illustrating an antenna module of a sixth modification.

FIG. 11 is a sectional view illustrating an antenna module of a seventh modification.

FIG. 12 is a sectional view illustrating an antenna module of an eighth modification.

FIG. 13 is a view illustrating an example of a first manufacturing process of the antenna module in FIG. 10.

FIG. 14 is a view illustrating an example of the first manufacturing process of the antenna module in FIG. 10.

FIG. 15 is a view illustrating an example of a second manufacturing process of the antenna module in FIG. 10.

FIG. 16 is a view illustrating an example of the second manufacturing process of the antenna module in FIG. 10.

FIG. 17 is a block diagram illustrating an example of a communication device to which an antenna module having a filter device formed using a multilayer substrate according to a second embodiment is applied.

FIG. 18 is a sectional view illustrating the antenna module of the second embodiment.

FIG. 19 is a perspective view illustrating the filter device included in the antenna module of the second embodiment.

FIG. 20 is a sectional view illustrating a transmission line according to a third embodiment.

FIG. 21 is a simulation result in which characteristics of a transmission line of the third embodiment and the transmission line having no filler (comparative example) are compared.

FIG. 22 is a sectional view illustrating a transmission line according to a modification of the third embodiment.

### DETAILED DESCRIPTION

In general, when a conventional dielectric substrate is applied to an antenna, a length of one side of an emission electrode included in the antenna is a half of a wavelength (effective wavelength) shortened by the effective permittivity in the dielectric.

When the effective permittivity in the dielectric is reduced, a wavelength shortening effect is weakened and the wavelength becomes longer, so that the length of one side of the emission electrode becomes longer. As a result, the size of the antenna module itself including the dielectric substrate increases, which may be a factor that hinders miniaturization. In addition, for example, when the dielectric substrate is applied to a device other than the antenna such as a filter device, the effective permittivity in the dielectric lowered to increase the size of a resonator. Furthermore, even in a case where the dielectric substrate is applied to the transmission line, the effective permittivity in the dielectric increases to lower the characteristic of an insertion loss.

The inventors developed the technologies in this disclosure to address the above-described problems. In particular, the inventors have developed the following technologies to improve a characteristic of a device such as an antenna including a dielectric substrate while reducing an effective permittivity in a dielectric and preventing an increase in size of the antenna including the dielectric substrate in a multilayer substrate applied to the device such as the antenna.

A multilayer substrate according to the present disclosure is a multilayer substrate including a plurality of dielectric layers, and the multilayer substrate includes a first electrode disposed on the plurality of dielectric layers and a first ground electrode disposed on the plurality of dielectric layers and disposed so as to be opposite to the first electrode in a multilayer direction. The plurality of dielectric layers includes a first layer and a second layer disposed between the first electrode and the first ground electrode, a filler having a permittivity lower than a permittivity of a base material of the plurality of dielectric layers is not disposed in the first layer, and, in the second layer, the filler is disposed in at least a part of a region where the first electrode and the first ground electrode overlap each other in planar view of the multilayer substrate from the multilayer direction.

A multilayer substrate according to another aspect is a multilayer substrate including a plurality of dielectric layers, and the multilayer substrate includes a first electrode disposed on the plurality of dielectric layers and a first ground electrode disposed on the plurality of dielectric layers and disposed so as to be opposite to the first electrode in a multilayer direction. In the multilayer substrate, the plurality of dielectric layers includes a first specific region and a second specific region between the first electrode and the first ground electrode, and the first electrode and the first ground electrode overlap each other in the first specific region and the first electrode and the first ground electrode do not overlap each other in the second specific region, in planar view of the multilayer substrate from the multilayer direction, at least a part of the first specific region includes a filler having a permittivity lower than a permittivity of a base material of the plurality of dielectric layers, and a permittivity of the first specific region is lower than a permittivity of the second specific region.

A method for manufacturing a multilayer substrate according to still another aspect of the present disclosure is a method for manufacturing a multilayer substrate including a plurality of dielectric layers. The multilayer substrate includes a first electrode and a ground electrode disposed so as to be opposite to the first electrode in the multilayer direction. A method for manufacturing a multilayer substrate includes: disposing a first dielectric layer with the ground electrode; disposing a second dielectric layer over the first dielectric layer; removing a dielectric of a first region of the second dielectric layer; filling the first region of the second dielectric layer with a member containing a filler; and disposing, above the second dielectric layer, a third dielectric layer with the first electrode, in which the filler has a permittivity lower than a permittivity of a base material of the plurality of dielectric layers.

A method for manufacturing a multilayer substrate according to another aspect of the present disclosure is a method for manufacturing a multilayer substrate including a plurality of dielectric layers. The multilayer substrate includes a first electrode and a ground electrode disposed so as to be opposite to the first electrode in the multilayer direction. The method for manufacturing a multilayer substrate includes: disposing a first dielectric layer with the ground electrode; disposing a second dielectric layer over the first dielectric layer; forming a via in the second dielectric layer; filling the via of the second dielectric layer with a member containing a filler; and disposing, above the second dielectric layer, a third dielectric layer with the first electrode, in which the filler has a permittivity lower than a permittivity of a base material of the plurality of dielectric layers.

In the multilayer substrate according to the present disclosure, the layer in which the filler having the permittivity lower than the permittivity of the base material forming the dielectric layer is disposed and the layer in which the filler is not disposed are included in at least a part of the region where the first electrode and the first ground electrode overlap each other in planar view of the multilayer substrate from the multilayer direction.

With such a configuration, the effective permittivity between the first electrode and the first ground electrode is reduced as compared with the case of the multilayer substrate in which the filler is not disposed in the above-described region, so that the characteristic of the device such as the antenna can be improved. In addition, the increase in a length of one side of the emission electrode is prevented as compared with the multilayer substrate in which the fillers are disposed in all the layers in the above-described region, so that the increase in the size of the antenna module or the like including the multilayer substrate can be prevented.

### First Embodiment

### Basic Configuration of Communication Device

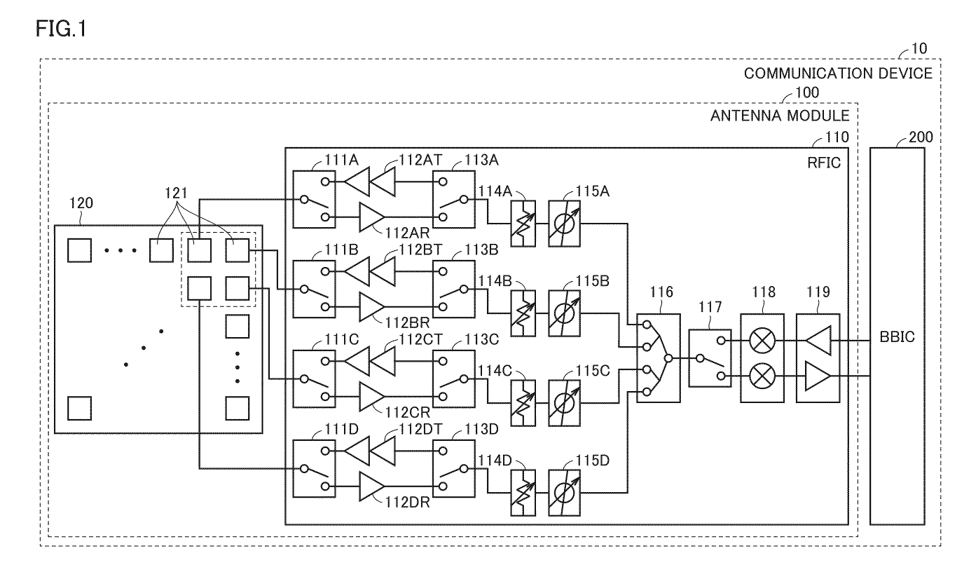

FIG. 1 is a block diagram illustrating an example of a communication device 10 to which an antenna module 100 formed using a multilayer substrate according to a first embodiment is applied. For example, communication device 10 is a mobile terminal such as a mobile phone, a smartphone, or a tablet, a personal computer having a communication function, or the like.

With reference to FIG. 1, communication device 10 includes antenna module 100 and a base band integrated circuit (BBIC) 200 constituting a base band signal processing circuit. Antenna module 100 includes a radio frequency integrated circuit (RFIC) 110 that is an example of a feeder circuit and an antenna array 120.

Communication device 10 up-converts the signal transferred from BBIC 200 to antenna module 100 into a high-frequency signal to emit the high-frequency signal from antenna array 120, and down-converts the high-frequency signal received by antenna array 120 and performs signal processing by BBIC 200.

In FIG. 1, for ease of description, only configurations corresponding to four emission electrodes 121 among a plurality of emission electrodes (antenna elements) 121 constituting antenna array 120 are illustrated, and configurations corresponding to other emission electrodes 121 having similar configurations are omitted.

RFIC 110 includes switches 111A to 111D, switches 113A to 113D, and switches 117, power amplifiers 112AT to 112DT, low noise amplifiers 112AR to 112DR, attenuators 114A to 114D, phase shifters 115A to 115D, a signal synthesizer and splitter 116, a mixer 118, and an amplifier circuit 119.

When the high-frequency signal is transmitted, switches 111A to 111D and switches 113A to 113D are switched to sides of power amplifiers 112AT to 112DT, and switch 117 is connected to the transmission-side amplifier of amplifier circuit 119. When the high-frequency signal is received, switches 111A to 111D and the switches 113A to 113D are switched to the sides of low noise amplifier 112AR to 112DR, and switch 117 is connected to the reception-side amplifier of amplifier circuit 119.

The signal transmitted from BBIC 200 is amplified by amplifier circuit 119 and up-converted by mixer 118. The transmission signal that is the up-converted high-frequency signal is split by signal synthesizer and splitter 116 into four, passes through four signal paths, and is supplied to different emission electrodes 121. At this point, directivity of antenna array 120 can be adjusted by individually adjusting phase shift degrees of phase shifters 115A to 115D disposed in the respective signal paths. Attenuators 114A to 114D adjust strength of the transmission signal.

In addition, the reception signal that is the high-frequency signal received by each emission electrode 121 is multiplexed by signal synthesizer and splitter 116 through four different signal paths. The multiplexed reception signal is down-converted by mixer 118, amplified by amplifier circuit 119, and transmitted to BBIC 200.

For example, RFIC 110 is formed as a one-chip integrated circuit component including the above circuit configuration. Alternatively, a device (switch, power amplifier, low noise amplifier, attenuator, phase shifter) corresponding to each emission electrode 121 in RFIC 110 may be formed as the one-chip integrated circuit component for each corresponding emission electrode 121.

### Structure of Antenna Module

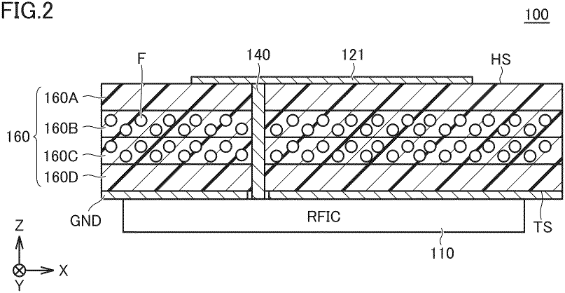

FIG. 2 is a sectional view of antenna module 100 of the first embodiment. With reference to FIG. 2, antenna module 100 includes emission electrode 121, a dielectric substrate 160, a ground electrode GND, and RFIC 110.

Dielectric substrate 160 has a multilayer structure in which a plurality of dielectric layers is laminated. Dielectric substrate 160 in FIG. 2 includes four layers of dielectric layers 160A, 160B, 160C, 160D. The number of dielectric layers included in dielectric substrate 160 is not limited to four.

For example, a base material forming each dielectric layer of dielectric substrate 160 is a resin such as epoxy or polyimide. The base material forming the dielectric layer may be a resin such as a liquid crystal polymer (LCP) having a lower permittivity, a fluorine-based resin, a polyethylene terephthalate (PET) material, or low temperature co-fired ceramics (LTCC). The dielectric layer may be a multilayer resin substrate formed by laminating a plurality of layers made of these resins.

In sectional views of the dielectric substrate in FIG. 2 and subsequent drawings, a normal direction (multilayer direction) of dielectric substrate 160 is defined as a Z-axis direction, and a plane perpendicular to the Z-axis direction is defined as an XY-plane. In addition, the positive direction of the Z-axis in each drawing may be referred to as an upper surface side or an upper side, and the negative direction may be referred to as a lower surface side or a lower side.

That is, a first surface HS is the upper surface of dielectric substrate 160, and a second surface TS is the lower surface of dielectric substrate 160. Ground electrode GND is mounted on second surface TS of dielectric substrate 160. Furthermore, RFIC 110 is mounted on the lower surface side of ground electrode GND with solder bumps interposed therebetween.

Ground electrode GND is disposed on the dielectric layer forming second surface TS of dielectric substrate 160. emission electrode 121 is disposed on the dielectric layer forming first surface HS of dielectric substrate 160. emission electrode 121 and ground electrode GND are made of a conductor such as copper or aluminum.

When planarly viewed from the normal direction of dielectric substrate 160, emission electrode 121 has a square or substantially square shape, and is disposed such that each side is parallel to the side of the rectangular dielectric substrate (and ground electrode GND). emission electrode 121 may not be disposed such that each side of emission electrode 121 is parallel to the side of the rectangular dielectric substrate (and ground electrode GND). Further, the shape of emission electrode 121 is not limited to a square, but may be a polygon, a circle, an ellipse, or a cross.

emission electrode 121 is electrically connected to RFIC 110 through a feeder line 140. Feeder line 140 penetrates ground electrode GND from RFIC 110 and is connected to a feeding point of emission electrode 121. In dielectric substrate 160, a plurality of fillers F are disposed in dielectric layer 160B and dielectric layer 160C.

As illustrated in FIG. 2, dielectric substrate 160 includes a plurality of dielectric layers between emission electrode 121 and ground electrode GND. emission electrode 121 corresponds to a “first electrode” in the present disclosure. Ground electrode GND corresponds to the “first ground electrode” in the present disclosure. Dielectric layers 160B, 160C in which the plurality of fillers F are disposed between emission electrode 121 and ground electrode GND correspond to the “second layer” in the present disclosure.

In dielectric layers 160B, 160C, the plurality of fillers F are disposed in at least a part of a region where emission electrode 121 and ground electrode GND overlap with each other in a planar view of antenna module 100 from the multilayer direction.

Dielectric substrate 160 includes dielectric layer 160A that is adjacent to dielectric layer 160B on which the plurality of fillers F are disposed and on which fillers F are not disposed. Furthermore, dielectric substrate 160 includes dielectric layer 160D that is adjacent to dielectric layer 160C in which the plurality of fillers F are disposed and in which fillers F are not disposed. Dielectric layers 160A, 160D in which filler F is not disposed correspond to the “first layer” in the present disclosure.

Filler F is formed of ceramics, glass, resin, or the like having the permittivity lower than that of the base material forming the dielectric layer. Filler F in FIG. 2 has a spherical shape, and may have a shape such as a polyhedron. A diameter of filler F is shorter than a film thickness (thickness in the Z-axis direction) of each dielectric layer, and for example, is 10 µm. For example, an upper limit of a volume content of filler F in the dielectric layer is 20% to 30%. Thus, antenna module 100 can contain the plurality of fillers F while maintaining strength of the entire dielectric substrate.

Filler F in FIG. 2 has a hollow structure. Specifically, filler F has a structure in which ceramics, glass, resin, or the like is used as an outer layer, and gas having the permittivity lower than that of the dielectric substrate is filled therein. For example, the gas filled inside is desirably air or gas having low relative permittivity. The inside of filler F may be vacuum. Thus, in the dielectric layer, the permittivity of the region where filler F is disposed is lower than that of the region where filler F is not disposed. In one aspect, filler F may have a solid structure made of ceramics, glass, resin, or the like without having the hollow structure.

In the antenna module in which the plurality of dielectric layers is laminated as described above, a frequency bandwidth of a radio wave that can be emitted from the emission electrode is affected by strength of an electromagnetic field coupling between the emission electrode and the ground electrode. The frequency bandwidth is narrowed as the strength of the electromagnetic field coupling increases, and the frequency bandwidth is widened as the strength of the electromagnetic field coupling decreases.

On the other hand, the strength of the electromagnetic field coupling is affected by the effective permittivity between the emission electrode and the ground electrode. More specifically, the electromagnetic field coupling becomes strong when the effective permittivity is high, and the electromagnetic field coupling becomes weak when the effective permittivity is low. That is, the frequency bandwidth can be widened by reducing the effective permittivity between the emission electrode and the ground electrode.

A length of one side of the emission electrode in planar view from the normal direction is affected not only by the frequency of the radio wave that can be emitted from the emission electrode but also by the effective permittivity between the emission electrode and the ground electrode. For example, the length of one side of the emission electrode is a width of emission electrode 121 in the X-axis direction in FIG. 2.

When the effective permittivity between the emission electrode and the ground electrode is reduced, the frequency bandwidth is widened while the length of one side of the emission electrode is increased, resulting in the increase in the size of the antenna module itself including the emission electrode.

In the communication device to which the antenna module such as the smartphone is applied, downsizing and thinning of the device are required. For this reason, when the length of one side of the emission electrode is increased, downsizing and thinning of the device may be hindered.

In addition, when the filler having the hollow structure is dispersed and disposed in all the dielectric layers, the decrease in the strength of the entire dielectric substrate may be caused.

In antenna module 100 of the first embodiment, as described above, the dielectric layer in which the plurality of fillers F are disposed is laminated between emission electrode 121 and ground electrode GND. Furthermore, dielectric layer 160A in which filler F is not disposed is laminated so as to be adjacent to dielectric layer 160B in which filler F is disposed. Dielectric layer 160D in which filler F is not disposed is laminated so as to be adjacent to dielectric layer 160C in which filler F is disposed. In general, the permittivity of air inside filler F is lower than the permittivity of the base material of dielectric substrate 160.

Consequently, when dielectric layers 160B, 160C in which the plurality of fillers F are disposed between emission electrode 121 and ground electrode GND are laminated, the effective permittivity between emission electrode 121 and ground electrode GND can be reduced. As a result, in antenna module 100 of the first embodiment, the frequency bandwidth of the emitted radio wave can be widened.

In addition, as compared with the dielectric substrate in which filler F is not disposed in all the dielectric layers, according to the multilayer substrate of the first embodiment, filler F is contained, so that a volume of the base material in the dielectric layer can be reduced to reduce the dielectric loss. Thus, the loss of electric energy in the dielectric can be reduced, so that efficiency in the antenna module can be improved.

Furthermore, in antenna module 100 of the first embodiment, dielectric substrate 160 includes dielectric layers 160A, 160D in which filler F is not disposed. Thus, excessive reduction in the effective permittivity between emission electrode 121 and ground electrode GND is prevented, so that the increase in the size of emission electrode 121 can be prevented to prevent the increase in the size of the antenna module itself.

Furthermore, in antenna module 100 of the first embodiment, dielectric substrate 160 includes dielectric layers 160A, 160D in which filler F is not disposed, so that the hollow structure portion formed of filler F in dielectric substrate 160 can be reduced to prevent the decrease in the strength of the entire dielectric substrate.

### Simulation Result

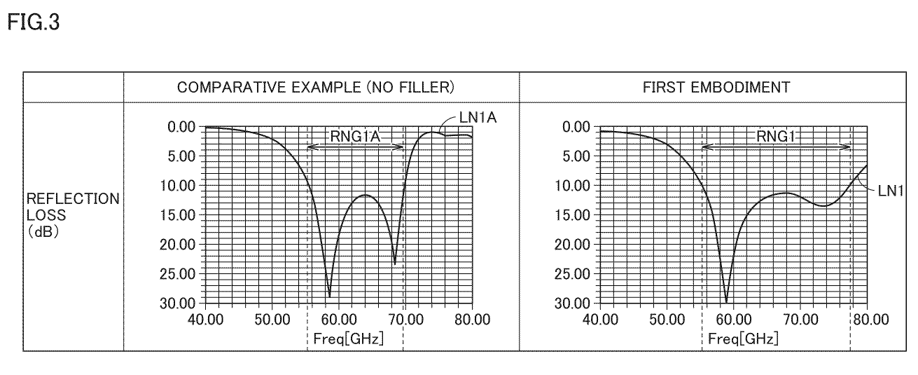

FIG. 3 is a simulation result in which antenna characteristics between antenna module 100 of the first embodiment and an antenna module without filler F (comparative example) are compared. In FIG. 3, a reflection characteristic is illustrated as the antenna characteristic.

In the following simulation, an example in which the frequency band used is the frequency band of a millimeter wave (GHz band) will be described, and the configuration of the present disclosure is also applicable to the frequency band other than the millimeter wave.

With reference to FIG. 3, in a reflection loss (line LN1A in FIG. 3) of the comparative example, the frequency band in which the reflection loss of 10 dB can be secured is in the range (RNG1A) of 55.4 GHz to 69.7 GHz, and the frequency bandwidth is 14.3 GHz. On the other hand, in the reflection loss (line LN1 in FIG. 3) of the first embodiment, the frequency band in which the reflection loss is less than 10 dB is in the range (RNG1) of 55.2 GHz to 77.1 GHz, and the frequency bandwidth is 21.9 GHz. As described above, antenna module 100 of the first embodiment has a wider frequency bandwidth than that of the comparative example.

### Manufacturing Process

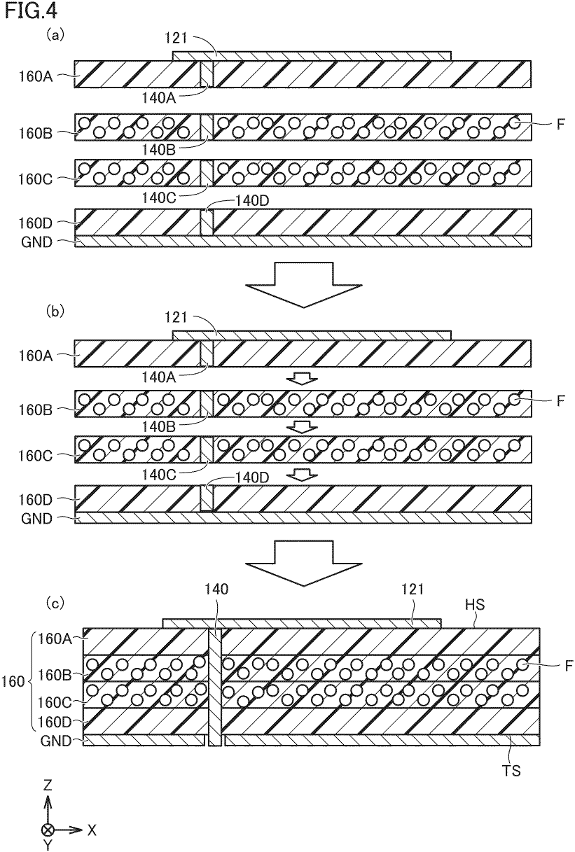

FIG. 4 is a view illustrating an example of a manufacturing process of antenna module 100 in FIG. 2. First, as illustrated in FIG. 4(a), each dielectric layer of dielectric substrate 160 is prepared as a dielectric sheet using low-temperature co-fired ceramics as the base material, and a via is formed in each dielectric layer. That is, feeder lines 140A to 140D are formed in dielectric layers 160A to 160D.

Feeder lines 140A to 140D are solidified by firing later to become feeder line 140. Thereafter, emission electrode 121 is bonded to the positive direction side of the Z-axis of dielectric layer 160A, and ground electrode GND is bonded to the negative direction side of the Z-axis of dielectric layer 160D.

In the first embodiment, the configuration in which emission electrode 121 is disposed on the surface of dielectric substrate 160 has been described as an example, and emission electrode 121 may be disposed inside dielectric substrate 160. That is, emission electrode 121 may not be exposed from dielectric substrate 160, and may be covered with a cover lay that is the dielectric layer of a resist or a thin film. Similarly, ground electrode GND may be formed inside the dielectric layer.

Thereafter, as illustrated in FIG. 4(b), dielectric layers 160C, 160B and dielectric layer 160A are sequentially laminated on dielectric layer 160D disposed on the negative direction side of the Z-axis from the positive direction side of the Z-axis.

Thereafter, as illustrated in FIG. 4(c), dielectric layers 160A to 160D are compressed, heated, and fired, whereby dielectric layers 160A to 160D come into close contact with each other.

Thus, feeder lines 140A to 140D are solidified by firing to form feeder line 140.

As a result, antenna module 100 in FIG. 2 is formed. As described above, in the manufacturing process of FIG. 4, dielectric layers 160C, 160B in which the plurality of fillers F are disposed and the dielectric layer 160A having the emission electrode are sequentially laminated above dielectric layer 160D including ground electrode GND, whereby the antenna module in FIG. 2 is formed. In the manufacturing process of FIG. 4, the vias are separately formed in the dielectric layers, but the vias may be collectively formed after the dielectric layers are laminated.

As described above, according to antenna module 100 of the first embodiment, in the antenna including the dielectric layer, the layer in which filler F is disposed and the layer in which filler F is not disposed are laminated between emission electrode 121 and ground electrode GND. Thus, the effective permittivity in the dielectric layer between emission electrode 121 and ground electrode GND can be reduced while the increase in the size of the antenna module itself is prevented, and the frequency bandwidth can be widened.

### First Modification

Antenna module 100 in FIG. 2 has the configuration in which dielectric layer 160B in which filler F is disposed and dielectric layer 160C are continuously laminated. By continuously laminating the dielectric layers in which filler F having a hollow structure is disposed, the strength of the region formed by dielectric layers 160B, 160C can be reduced as compared with other regions in antenna module 100.

In the following first modification, an antenna module 100A that does not have a configuration in which dielectric layers in which filler F having the hollow structure is disposed are continuously laminated will be described.

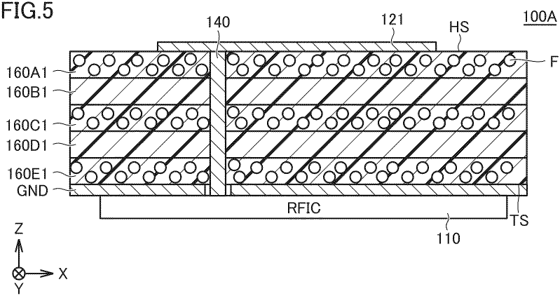

FIG. 5 is a sectional view illustrating antenna module 100A of the first modification. Unlike the configuration of antenna module 100 in FIG. 2, antenna module 100A in FIG. 5 has a configuration in which five dielectric layers 160A1 to 160E1 are laminated. Also in FIG. 5 and subsequent figures, the plurality of laminated dielectric layers is referred to as dielectric substrate 160.

As illustrated in FIG. 5, in antenna module 100A, a plurality of fillers F are disposed in dielectric layers 160A1, 160C1, 160E1. That is, antenna module 100A has a configuration in which the dielectric layer in which the plurality of fillers F are disposed and the dielectric layer in which filler F is not disposed are alternately laminated.

As described above, antenna module 100A of the first modification does not have the configuration in which the dielectric layers in which the plurality of fillers F are disposed are continuously laminated, so that the decrease in the strength of the dielectric substrate can be prevented while the effective permittivity is reduced in antenna module 100A.

### Second Modification

Antenna module 100A in FIG. 5 has the configuration in which the plurality of fillers F are disposed in dielectric layer 160A1 forming first surface HS and dielectric layer 160E1 forming second surface TS. Filler F is not necessarily filled in the dielectric layer so as to be completely covered by the base material of the dielectric layer.

That is, after firing, a part of fillers F may protrude from the surface of the dielectric layer. In other words, because a part of the filler F protrudes from the surface of the dielectric layer, the surface of the dielectric layer becomes a surface having a non-flat uneven portion.

When the surface of dielectric substrate 160 grounded to emission electrode 121 or ground electrode GND has the uneven portion, adhesion between emission electrode 121 or ground electrode GND and the dielectric substrate is lowered, and the emission electrode and/or the ground electrode may be peeled off from the dielectric substrate.

In addition, flatness of the emission electrode is lowered, and the directivity of the radio wave emitted by emission electrode 121 may change. Furthermore, in dielectric substrate 160, first surface HS exposed to the outside has the uneven portion, so that the aesthetic appearance of antenna module 100 itself may be impaired.

In the following second modification, an antenna module 100B having a configuration in which filler F is not disposed in the dielectric layer forming first surface HS and second surface TS will be described.

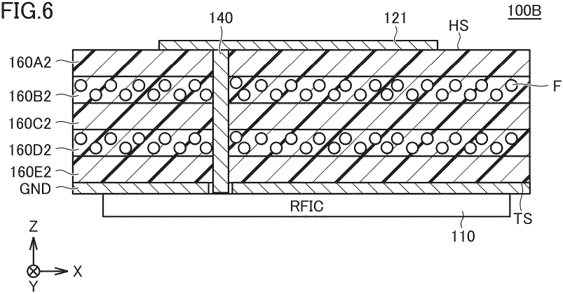

FIG. 6 is a sectional view illustrating antenna module 100B of the second modification. In antenna module 100B of FIG. 6, unlike the configuration of antenna module 100A in FIG. 5, a dielectric layer 160A2 forming first surface HS and a dielectric layer 160B2 forming second surface TS are not filled with filler F.

As described above, in antenna module 100B of the second modification, because filler F is not disposed on dielectric layer 160A2 forming first surface HS and dielectric layer 160B2 forming second surface TS, the uneven portion due to the protrusion of filler F is not generated on first surface HS and second surface TS.

In addition, because antenna module 100B of the second modification does not have the configuration in which the dielectric layers in which the plurality of fillers F are disposed are continuously laminated, the decrease in the strength of the dielectric substrate can be prevented while the effective permittivity is reduced in antenna module 100B.

Accordingly, the decrease in adhesion of emission electrode 121 or ground electrode GND can be prevented in antenna module 100B. In addition, the change of the directivity of the radio wave due to the decrease in the adhesion can be prevented in antenna module 100B. Furthermore, in antenna module 100B, the uneven portion is not formed on exposed first surface HS, so that the aesthetic appearance of antenna module 100B can be prevented from being impaired.

In the second modification, “dielectric layer 160A2” corresponds to the “third layer” of the present disclosure. “Dielectric layer 160E2” corresponds to the “fourth layer” of the present disclosure.

### Third Modification

The antenna module in which dielectric substrate 160 is configured on one substrate has been described in the first modification and the second modification. In the following third modification, a configuration in which dielectric substrate 160 includes a plurality of substrates will be described.

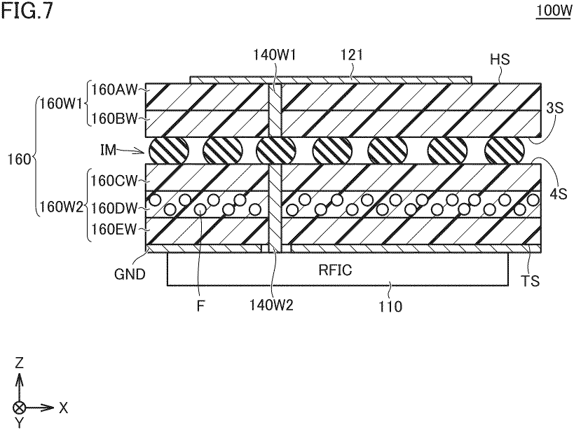

FIG. 7 is a sectional view illustrating an antenna module 100W of the third modification. Antenna module 100W includes a substrate 160W1 including dielectric layers 160AW, 160BW and a substrate 160W2 including dielectric layers 160CW, 160EW. In addition, antenna module 100W includes an intermediate member IM between substrate 160W1 and substrate 160W2. In the third modification, intermediate member IM is a plurality of solder bumps. For example, intermediate member IM may be a conductive paste or a multipolar connector.

As illustrated in FIG. 7, dielectric substrate 160 includes substrate 160W1 on which emission electrode 121 is formed and substrate 160W2 on which ground electrode GND is formed as different substrates. Substrate 160W1 includes a feeder line 140W1. Substrate 160W2 includes a feeder line 140W2. Feeder line 140W1 is electrically connected to feeder line 140W2 through intermediate member IM.

A surface 3S is a surface of a dielectric layer 160BW on the negative direction side of the Z-axis. A surface 4S is a surface of a dielectric layer 160CW on the positive direction side of the Z-axis. As illustrated in FIG. 7, intermediate member IM is disposed so as to be in contact with at least a part of each of surface 3S and surface 4S. In the example of FIG. 7, filler F is disposed inside a dielectric layer 160DW. For example, filler F may be disposed in another dielectric layer such as dielectric layer 160BW. That is, filler F may be disposed in the dielectric layer included in substrate 160W1, or may be disposed in both the dielectric layer included in substrate 160W1 and the dielectric layer included in substrate 160W2.

In addition, intermediate member IM is not limited to be disposed between dielectric layers 160BW, 160CW, but for example, may be disposed between dielectric layers 160CW, 160DW. In this case, surface 3S is formed on the negative direction side of the Z-axis in dielectric layer 160CW, and surface 4S is formed on the positive direction side of the Z-axis in dielectric layer 160DW. In FIG. 7, the example in which dielectric substrate 160 includes two substrates of substrates 160W1, 160W2 has been described. However, dielectric substrate 160 may include three or more dielectric substrates.

As described above, even in the configuration in which dielectric substrate 160 includes the plurality of substrates, the effective permittivity in the dielectric layer between emission electrode 121 and ground electrode GND can be reduced by disposing filler F, and the frequency bandwidth can be widened. In addition, when intermediate member IM is disposed, antenna module 100W can be physically separated into substrates 160W1, 160W2. That is, substrates 160W1, 160W2 can be different substrates. In the third modification, “substrate 160W1” and “substrate 160W2” correspond to “first substrate” and the “second substrate” of the present disclosure, respectively.

### Fourth Modification

The antenna module having single emission electrode 121 has been described as the antenna module described in the first to third modifications. In the following fourth modification and fifth modification, a configuration in which the feature of the present disclosure is applied to a stack-type antenna module will be described.

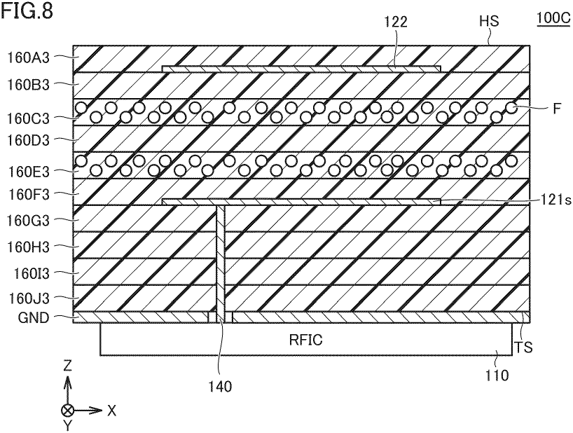

FIG. 8 is a sectional view illustrating an antenna module 100C of the fourth modification. Antenna module 100 C includes laminated dielectric layers 160A3 to 160J3. Antenna module 100 C includes a feed element 121s and a parasitic element 122 as emission electrodes. Parasitic element 122 is formed in dielectric layer 160A3.

On the other hand, feed element 121s is disposed on dielectric substrate 160 so as to be opposite to parasitic element 122. Feed element 121s and parasitic element 122 are set to have substantially the same size and substantially the same resonance frequency.

On dielectric substrate 160, ground electrode GND is disposed opposite to feed element 121s. Ground electrode GND is disposed below feed element 121s (in the negative direction of the Z-axis), and feed element 121s is disposed in a layer between ground electrode GND and parasitic element 122.

Dielectric layers 160C3, 160E3 in which the plurality of fillers F are disposed are disposed between feed element 121s and parasitic element 122.

In antenna module 100C, parasitic element 122 having a close resonance frequency is disposed in the emission direction of feed element 121s, so that the frequency bandwidth of the radio wave that can be emitted can be widened. In addition, filler F having the permittivity lower than the permittivity of the base material forming the dielectric layer is disposed between parasitic element 122 and feed element 121s, so that the frequency bandwidth can be further widened.

Although FIG. 8 illustrates the example in which filler F is disposed only between parasitic element 122 and feed element 121s, filler F may be disposed between feed element 121s and ground electrode GND.

In FIG. 8, parasitic element 122 is disposed inside the dielectric layer, However, parasitic element 122 may be disposed so as to be exposed to the outside of the dielectric layer.

In the fourth modification, “parasitic element 122” and “feed element 121s” correspond to the “first emitting element” and the “second emitting element” of the present disclosure, respectively. “Dielectric layer 160C3” and “dielectric layer 160E3” correspond to the “fifth layer” of the present disclosure. Furthermore, “dielectric layer 160B3”, “dielectric layer 160D3”, and “dielectric layer 160F3” correspond to the “sixth layer” of the present disclosure.

### Fifth Modification

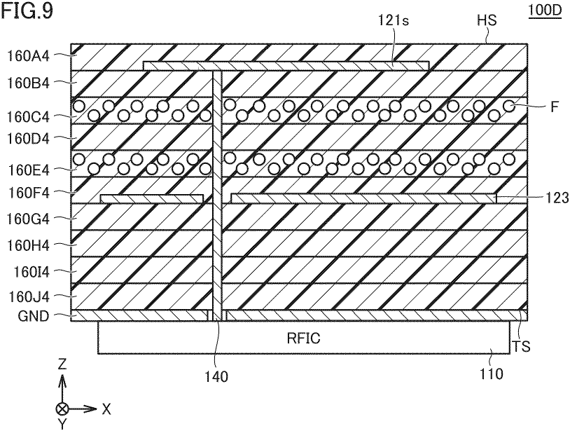

In a fifth modification, a dual-band-type antenna module will be described. FIG. 9 is a sectional view illustrating an antenna module 100D of the fifth modification.

Antenna module 100D is different from antenna module 100C of the fourth modification in the disposition of the emitting element. The description of the configuration of antenna module 100D overlapping with that of antenna module 100C will not be repeated.

With reference to FIG. 9, antenna module 100D includes laminated dielectric layers 160A4 to 160J4. Antenna module 100D includes feed element 121s disposed on a dielectric substrate and parasitic element 123 disposed on dielectric substrate 160 as emitting elements. Feed element 121s and parasitic element 123 are disposed opposite to each other, and parasitic element 123 is disposed between feed element 121s and ground electrode GND. The size of parasitic element 123 is larger than the size of feed element 121s. That is, the resonance frequency of feed element 121s is higher than the resonance frequency of parasitic element 123.

Feeder line 140 penetrates ground electrode GND and parasitic element 123 from RFIC 110 and is connected to feed element 121s. When the high-frequency signal corresponding to the resonance frequency of feed element 121s is supplied from RFIC 110 to feeder line 140, the radio wave is emitted from feed element 121s.

When the high-frequency signal corresponding to the resonance frequency of parasitic element 123 is supplied to feeder line 140, feeder line 140 and parasitic element 123 are electromagnetically coupled to each other, and the radio wave is emitted from parasitic element 123. That is, antenna module 100D functions as the dual-band-type antenna module.

A layer in which filler F having the permittivity lower than the permittivity of the base material forming the dielectric layer is disposed is laminated between feed element 121s and parasitic element 123 in antenna module 100D of the fifth modification. Consequently, in particular the bandwidth of the radio wave emitted from feed element 121s can be widened.

Also in antenna module 100D, parasitic element 123 may be disposed so as to be exposed from dielectric substrate 160.

Although FIG. 8 illustrates the example in which filler F is disposed only between parasitic element 122 and feed element 121s, filler F may be disposed between feed element 121s and ground electrode GND.

In the fifth modification, “feed element 121s” and “parasitic element 123” correspond to the “first emitting element” and the “second emitting element” of the present disclosure, respectively.

“Dielectric layer 160C4” and “dielectric layer 160E4” correspond to the “fifth layer” of the present disclosure. Furthermore, “dielectric layer 160B4”, “dielectric layer 160D4”, and “dielectric layer 160F4” correspond to the “sixth layer” of the present disclosure.

### Sixth Modification

In the first to fifth modifications, the antenna module having the configuration in which the dielectric layer in which filler F is dispersed and mixed and the dielectric layer in which filler F is not dispersed and mixed are laminated has been described. In the following the sixth modification and seventh modification, a configuration in which a plurality of fillers F are dispersed and mixed in a partial region of dielectric substrate 160 will be described focusing on the partial region.

In the dielectric layer, the strength of the region in which filler F is disposed may be lower than the strength of the region in which filler F is not disposed. Accordingly, desirably the region in which filler F is disposed becomes narrow from the viewpoint of the strength of the dielectric substrate.

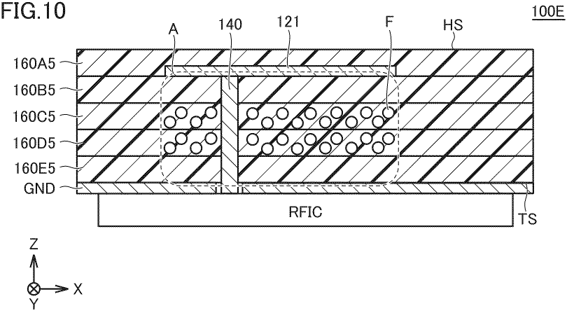

As illustrated in FIG. 10, in the sixth modification, an antenna module 100E in which filler F having the hollow structure is disposed in a region A where the electromagnetic field coupling between emission electrode 121 and ground electrode GND is strong will be described. Antenna module 100E includes laminated dielectric layers 160A5 to 160E5.

Region A is a region indicating a space between emission electrode 121 and ground electrode GND, and is a region where the electromagnetic field coupling is strong. Accordingly, region A is a region in which the frequency bandwidth of the radio wave emitted by antenna module 100E is easily widened by reducing the effective permittivity as compared with the region other than region A in dielectric substrate 160.

FIG. 10 is a sectional view illustrating antenna module 100E of the sixth modification. As illustrated in FIG. 10, in antenna module 100E, filler F is disposed in the region in which an electric line of force generated between emission electrode 121 and ground electrode GND is considered.

That is, in planar view from the normal direction of dielectric substrate 160, filler F is disposed in dielectric layers 160C5, 160D5 between emission electrode 121 and ground electrode GND in region A where emission electrode 121 and ground electrode GND overlap with each other.

As described above, in antenna module 100E of the sixth modification, filler F is disposed only in region A where the electromagnetic field coupling between emission electrode 121 and ground electrode GND is strong. As a result, the frequency bandwidth of the emitted radio wave can be widened while the decrease in the strength of antenna module 100E itself is prevented.

In FIG. 10, filler F is not disposed in dielectric layers 160B5, 160E5. However, in one aspect, filler F may also be disposed in region A of dielectric layers 160B5, 160E5. Furthermore, filler F may be disposed in the region where emission electrode 121 and ground electrode GND do not overlap each other when emission electrode 121 is viewed from the normal direction in planar view. For example, filler F may be disposed in the region where region A in FIG. 10 is expanded in each of the positive direction and the negative direction in the X-axis direction. For example, the extension length of region A is a length of λ/8 from the end of emission electrode 121 when the length of the wavelength shortened by the effective permittivity in the dielectric is λ.

In the sixth modification, “region A” corresponds to the “first specific region” of the present disclosure, and the “region other than region A in dielectric substrate 160” corresponds to the “second specific region” of the present disclosure.

### Seventh Modification

In a seventh modification, an antenna module having a configuration in which the plurality of fillers F are disposed in the region having stronger electromagnetic field coupling in region A will be described.

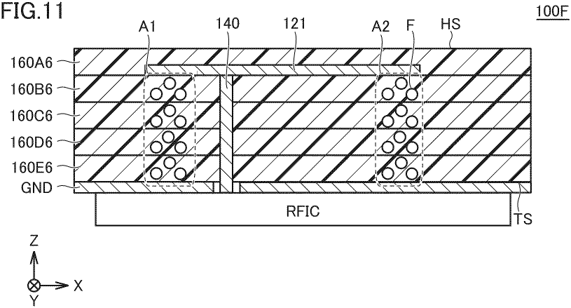

FIG. 11 is a sectional view illustrating an antenna module 100F of the seventh modification. As illustrated in FIG. 10, region A was the region where the electromagnetic field coupling was strong in dielectric substrate 160.

FIG. 11 illustrates an example in which filler F is disposed in the region where the electromagnetic field coupling is further stronger. In the electromagnetic field coupling between emission electrode 121 and ground electrode GND, the electromagnetic field coupling generated from the end of emission electrode 121 is stronger than the electromagnetic field coupling generated from the vicinity of the center of emission electrode 121. This is because, the magnitude of the electric field gradually increases from the center of emission electrode 121 to the side orthogonal to the polarization direction in emission electrode 121. Accordingly, an example in which filler F is disposed in the vicinity of the end side with respect to the center of emission electrode 121 will be described below.

That is, regions A1, A2 located in the vicinity of the end of emission electrode 121 illustrated in FIG. 11 are regions having strong electromagnetic field coupling in region A. Accordingly, in antenna module 100F of FIG. 11, filler F is disposed in regions A1, A2. The length of region A1 in the X-axis direction is desirably a length of λ/8 with respect to the positive direction of the X-axis from the end of emission electrode 121. Similarly, the length of region A2 in the X-axis direction is desirably the region from the end of emission electrode 121 to the length of λ/8 in the negative direction of the X-axis.

As described above, in antenna module 100F of the seventh modification, filler F is disposed only in regions A1, A2 where the electromagnetic field coupling is stronger in region A. Thus, when the disposition of filler F in the region of dielectric substrate 160 where the influence on the antenna characteristics is small is prevented, the strength of dielectric substrate 160 itself can be prevented from decreasing while the wide frequency bandwidth of the emitted radio wave is maintained.

In the seventh modification, “region A1” and “region A2” correspond to the “first specific region” of the present disclosure, and “region of dielectric substrate where emission electrode 121 and ground electrode GND do not overlap each other when planarly viewed from normal direction” corresponds to the “second specific region” of the present disclosure.

In FIG. 11, regions A1, A2 are included in region A where emission electrode 121 and ground electrode GND overlap with each other. However, regions A1, A2 may not be included in region A where emission electrode 121 and ground electrode GND overlap with each other.

As described above, the magnitude of the electric field is maximized at the end of emission electrode 121, and the electromagnetic field coupling between emission electrode 121 and ground electrode GND becomes strong in the vicinity of the end of emission electrode 121.

The electric line of force generated from the end of emission electrode 121 passes through the region further outside emission electrode 121 from the end to ground electrode GND. For this reason, the region where the electromagnetic field coupling is strong is the region further expanded than the region where emission electrode 121 and ground electrode GND overlap each other in planar view from the normal direction.

Accordingly, regions A1, A2 illustrated in the seventh modification may be expanded so as to extend to the expanded region. When the length of the wavelength shortened by the effective permittivity in the dielectric is λ, region A1 may include the region obtained by extending the length of λ/8 from the end of emission electrode 121 in the negative direction of the X-axis. Further, region A2 may include the region where the length of λ/8 from the end of emission electrode 121 is extended in the positive direction of the X-axis. As a result, regions A1, A2 can include the region having the intensity higher than or equal to a half of the highest electric field intensity.

### Eighth Modification

In an eighth modification, a configuration in which the feature of the sixth modification is applied to a stack-type antenna module 100G will be described.

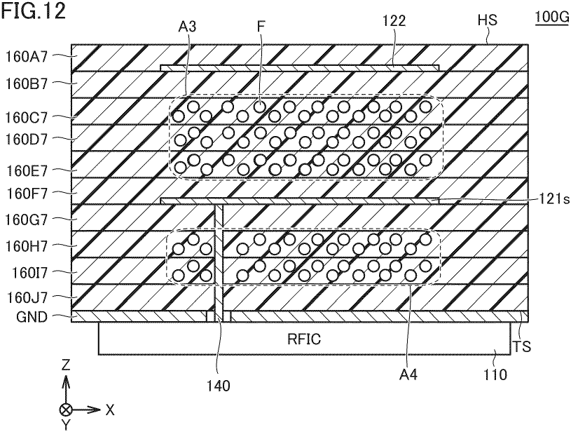

FIG. 12 is a sectional view illustrating an antenna module 100G of the eighth modification. Antenna module 100G in FIG. 12 includes parasitic element 122 in addition to the configuration of antenna module 100E in FIG. 10. Feed element 121s is electromagnetically coupled to parasitic element 122. The region where parasitic element 122 and feed element 121s overlap each other when antenna module 100G is viewed in planar view is the region where the electromagnetic field coupling between parasitic element 122 and feed element 121s is strong.

In feed element 121s, the magnitude of the electric field gradually increases from the center of feed element 121s to the side orthogonal to the polarization direction. Accordingly, the magnitude of the electric field is maximized on the side orthogonal to the polarization direction of feed element 121s. Consequently, in FIG. 12, when antenna module 100G is viewed in planar view, filler F having the permittivity lower than the permittivity of the base material forming the dielectric layer is disposed in region A3 where feed element 121s and parasitic element 122 overlap each other.

On the other hand, in dielectric layers 160G7 to 160J7, filler F is not disposed in the region where feed element 121s and ground electrode GND do not overlap each other when antenna module 100G is viewed in planar view.

When filler F having the permittivity lower than the permittivity of the base material forming the dielectric layer in region A3 is disposed, the frequency bandwidth can be further widened. Filler F may be disposed in the region obtained by expanding region A3. Filler F may also be disposed in dielectric layers 160B7, 160F7, 160G7, 160J7. Alternatively, the configuration of antenna module 100G is also applicable to the dual-band-type antenna module as illustrated in FIG. 9.

In the eighth modification, “region A3” corresponds to the “third specific region” of the present disclosure, and “region A” corresponds to the “first specific region” of the present disclosure. “In dielectric layers 160B7 to 160F7, the region where feed element 121s and parasitic element 122 do not overlap each other when antenna module 100G is viewed in planar view” corresponds to the “fourth specific region” of the present disclosure, and “in dielectric layers 160G7 to 160J7, the region where feed element 121s and ground electrode GND do not overlap each other when antenna module 100G is viewed in planar view” corresponds to the “second specific region” of the present disclosure.

### First Manufacturing Process of Sixth Modification

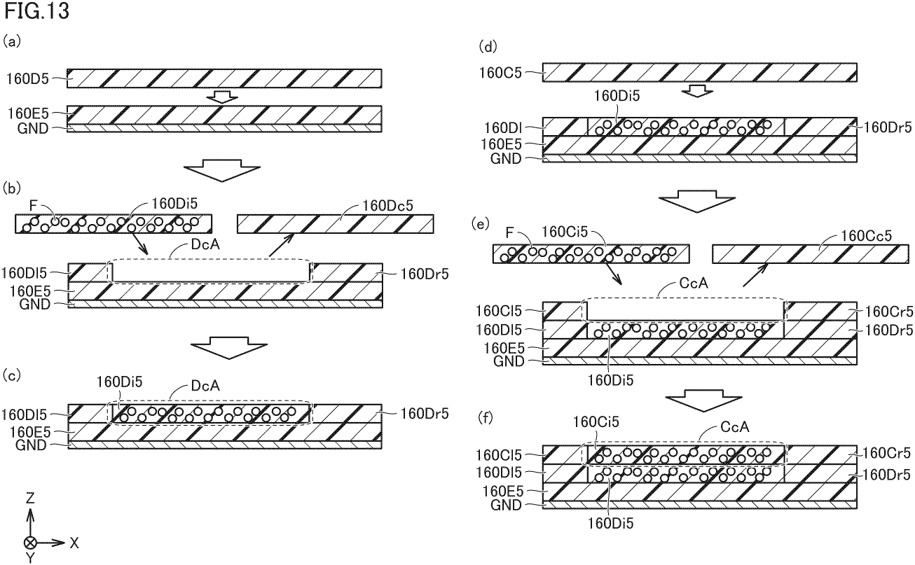

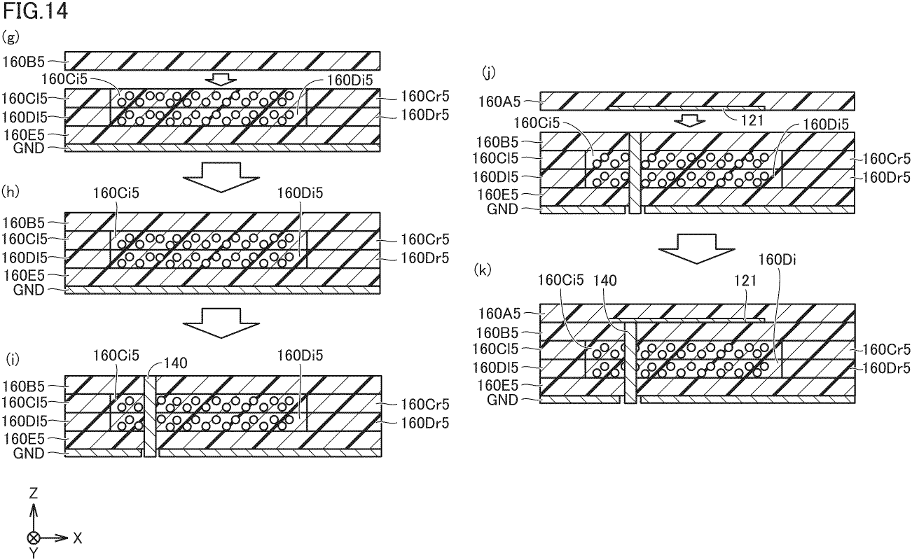

FIGS. 13 and 14 are views illustrating an example of a first manufacturing process of antenna module 100E in FIG. 10. First, dielectric sheets of dielectric layers 160E5, 160D5 having ground electrode GND are prepared as illustrated in FIG. 13(a).

Dielectric layer 160E5 in which ground electrode GND is formed is disposed, and dielectric layer 160D5 is laminated above dielectric layer 160E5.

Thereafter, a part of dielectric layer 160D5 disposed in a region DcA is removed as illustrated in FIG. 13(b). A dielectric layer 160Dc5 is a part of dielectric layer 160D5 disposed in region DcA.

When dielectric layer 160Dc5 is removed, a dielectric layer 160Dl5 of dielectric layer 160D5 located on the negative direction side in the X-axis direction in FIG. 13 keeps the state in which dielectric layer 160Dl5 is laminated on dielectric layer 160E5. In addition, when dielectric layer 160Dc5 is removed, a dielectric layer 160Dr5 of dielectric layer 160D5 located on the positive direction side in the X-axis direction in FIG. 13 keeps the state in which dielectric layer 160Dr5 is laminated above dielectric layer 160E5.

Thereafter, as illustrated in FIG. 13(c), a dielectric layer 160Di5 made of a member containing the plurality of fillers F is filled in region DcA instead of removed dielectric layer 160Dc5.

Thereafter, as illustrated in FIG. 13(d), dielectric layer 160C5 is laminated on dielectric layers 160Dl5, 160Di5, 160Dr5.

Thereafter, the part of a region CcA in dielectric layer 160C5 is removed as illustrated in FIG. 13(e). Dielectric layer 160Cc5 is a part of dielectric layer 160C5 disposed in region CcA.

Thereafter, as illustrated in FIG. 13(f), dielectric layer 160Ci5 made of the member containing the plurality of fillers F is filled in region CcA instead of removed dielectric layer 160Cc5.

In the processes in FIGS. 13(b) to 13(f), dielectric layers 160Dc5, 160Cc5 may be collectively removed after dielectric lays 160D5, 160C5 are laminated above dielectric layer 160E5. Dielectric layers 160Di5, 160Ci5 are filled in regions DcA, CcA after dielectric layers 160Dc5, 160Cc5 are collectively removed.

When the process in FIG. 13(f) is completed, the process proceeds to the process in FIG. 14(g). In FIG. 14(g), dielectric layer 160B5 is laminated on dielectric layers 160Cl5, 160Ci5, 160Cr5.

As illustrated in FIG. 14(h), dielectric layer 160B5 maintains the state in which dielectric layer 160B5 is laminated on dielectric layers 160Cl5, 160Ci5, 160Cr5.

Thereafter, as illustrated in FIG. 14(i), a via is formed so as to penetrate dielectric layers 160B5, 160Ci5, 160Di5, 160E5 and ground electrode GND, and the conductive paste is filled in the via. Thus, feeder line 140 is formed.

Thereafter, as illustrated in FIG. 14(j), dielectric layer 160A5 on which emission electrode 121 is formed is laminated above the dielectric layer in FIG. 14(i).

All the laminated dielectric layers are solidified and brought into close contact with each other by being compressed, heated, and fired.

As a result, as illustrated in FIG. 14(k), antenna module 100E in FIG. 10 is formed. As described above, in the first manufacturing process of antenna module 100E in FIGS. 13 and 14, after the dielectric layer not containing filler F is laminated, the dielectric disposed in region DcA or CcA of the dielectric layer is replaced with the dielectric containing filler F, whereby antenna module 100E in FIG. 10 can be manufactured. In the first manufacturing process, dielectric layer 160D5 is disposed on the negative direction side of the Z-axis to laminate other dielectric layers from above. However, all the dielectric layers may be reversed, and dielectric layer 160A5 may be disposed on the negative direction side of the Z-axis and other dielectric layers may be laminated from above.

In the first manufacturing process of the sixth modification, “dielectric layer 160E5” corresponds to the “first dielectric layer” of the present disclosure. “Dielectric layer 160D5” corresponds to the “second dielectric layer” of the present disclosure.

Furthermore, “region DcA” corresponds to the “first region” of the present disclosure. “Dielectric layer 160Di5” corresponds to the “member containing the filler having the permittivity lower than the permittivity of the base material forming the dielectric layer” of the present disclosure. Furthermore, “dielectric layer 160A5” corresponds to the “third dielectric layer” of the present disclosure.

### Second Manufacturing Process of Sixth Modification

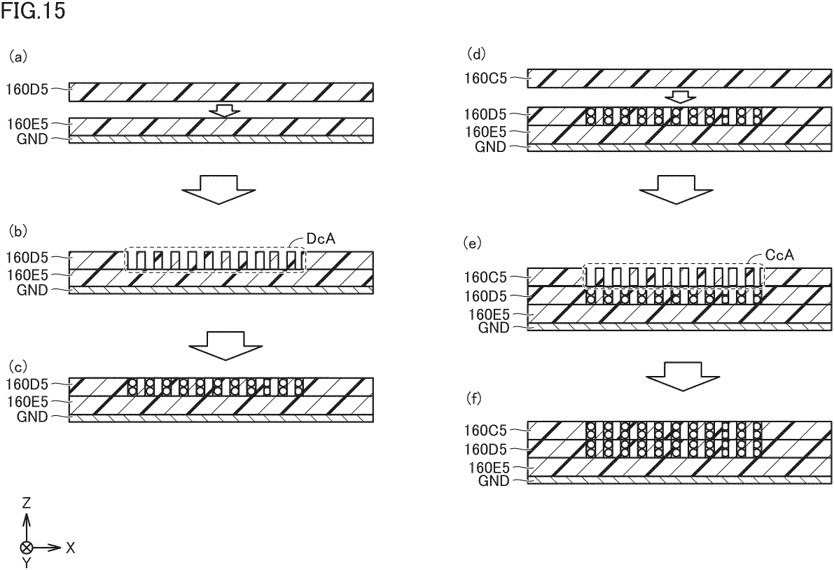

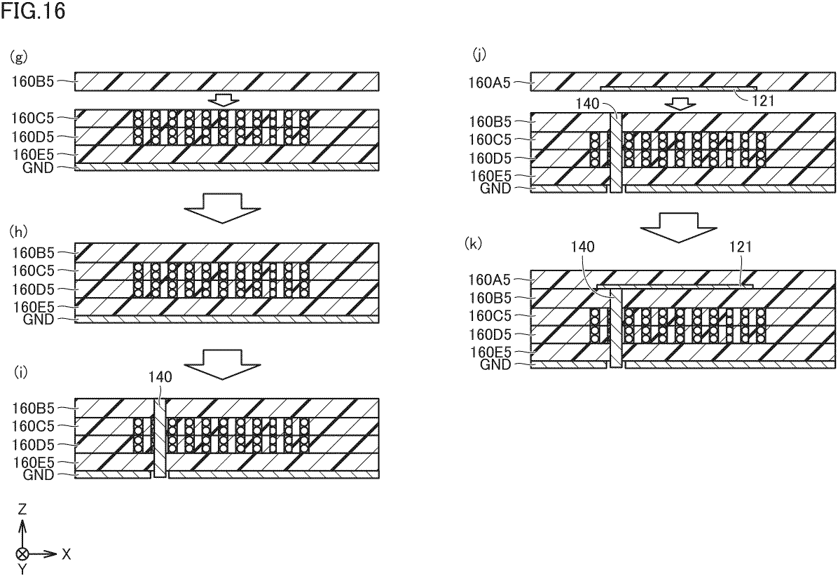

FIGS. 15 and 16 are views illustrating an example of a second manufacturing process of antenna module 100E in FIG. 10. In the description of the second manufacturing process, the description overlapping with the first manufacturing process will not be repeated.

First, as illustrated in FIG. 15(a), dielectric layer 160E5 on which ground electrode GND is formed is disposed, and dielectric layer 160D5 is laminated above dielectric layer 160E5. Thereafter, in dielectric layer 160D5, a plurality of vias is formed in region DcA as illustrated in FIG. 15(b). Because the vias are formed to fill filler F, the diameters of the vias are larger than the diameter of filler F.

Thereafter, as illustrated in FIG. 15(c), the member containing filler F is filled in the plurality of vias formed in region DcA. Thereafter, in FIGS. 15(d) to 15(f), processes corresponding to FIGS. 15(a) to 15(c) are repeatedly executed.

When the process in FIG. 15(f) is completed, the process proceeds to the process in FIG. 16(g). FIGS. 16(g) to 16(k) correspond to FIGS. 14(g) to 14(k). As a result, as illustrated in FIG. 16(k), antenna module 100E in FIG. 10 is formed.

As described above, in the second manufacturing process of antenna module 100E in FIGS. 15 and 16, after the dielectric layer not containing filler F is laminated, the plurality of vias is formed in region DcA or CcA, and the plurality of vias are filled with the member containing filler F, whereby antenna module 100E in FIG. 10 can be manufactured.

### Second Embodiment

In the first embodiment, the configuration of the antenna module using the multilayer substrate in which the dielectric layer in which filler F is disposed and the dielectric layer in which filler F is not disposed are laminated in the region between emission electrode 121 and ground electrode GND to reduce the effective permittivity of the region and widen the frequency bandwidth while preventing the increase in the size of the emission electrode has been described.

The multilayer substrate used in the first embodiment can be used not only for the antenna module but also for a filter including a resonator and the ground electrode.

In a second embodiment, a configuration in which the characteristic of the filter is improved by disposing the filler in the dielectric layer between the resonator functioning as the filter and the ground electrode will be described.

In the filter that includes the resonator disposed between two ground electrodes opposite to each other, the size of the resonator is affected by the height of the effective permittivity between each ground electrode and the resonator. The increase of the effective permittivity between the resonator and the ground electrode reduces the size of the resonator.

### Basic Configuration of Communication Device

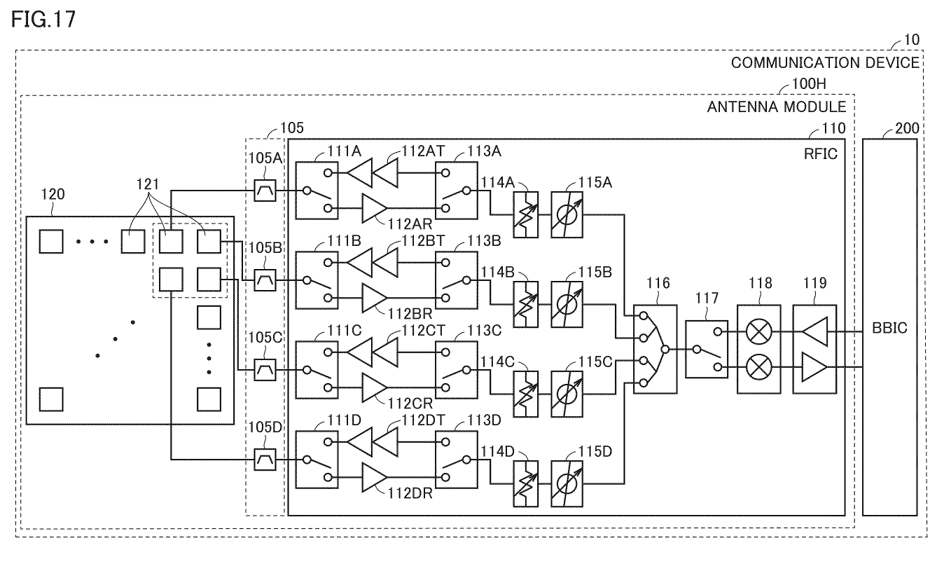

FIG. 17 is a block diagram illustrating an example of communication device 10 to which an antenna module 100H having a filter device formed using a multilayer substrate of the second embodiment is applied.

In antenna module 100H of the second embodiment, the description of the configuration overlapping antenna module 100 of the first embodiment will not be repeated.

Antenna module 100H includes a filter device 105 in addition to the configuration of antenna module 100 of the first embodiment. Filter device 105 removes unnecessary waves included in the transmission signal and/or the reception signal.

Communication device 10 up-converts the signal transferred from BBIC 200 to antenna module 100H into the high-frequency signal by RFIC 110, and emits the high-frequency signal from antenna array 120 through filter device 105. In addition, communication device 10 transmits the high-frequency signal received by antenna array 120 to RFIC 110 through filter device 105, down-converts the high-frequency signal, and processes the high-frequency signal by BBIC 200.

Filter device 105 includes filters 105A to 105D. Filters 105A to 105D are connected to switches 111A to 111D in RFIC 110, respectively. Filters 105A to 105D have a function of attenuating a signal in a specific frequency band. Filters 105A to 105D may be bandpass filters, a high-pass filters, a low-pass filters, or a combination thereof. Furthermore, antenna module 100H can include filter device 105 between switch 117 and mixer 118.

Although filter device 105 and antenna array 120 are individually illustrated in FIG. 1, filter device 105 is formed inside antenna array 120 as described later in the present disclosure.

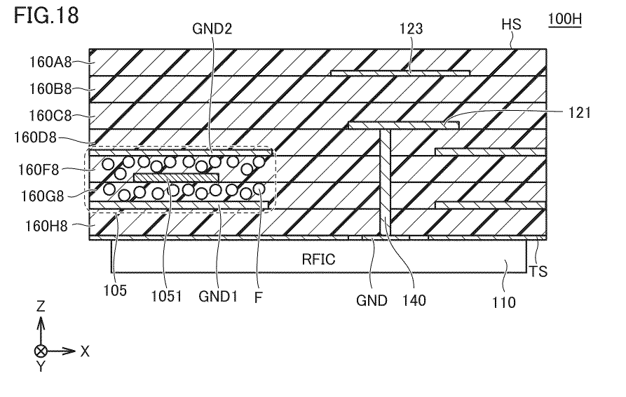

FIG. 18 is a sectional view illustrating antenna module 100H of the second embodiment. Antenna module 100H in FIG. 18 is the dual-band-type antenna module. Antenna module 100H includes laminated dielectric layers 160A8 to 160H8 and filter device 105 in dielectric substrate 160.

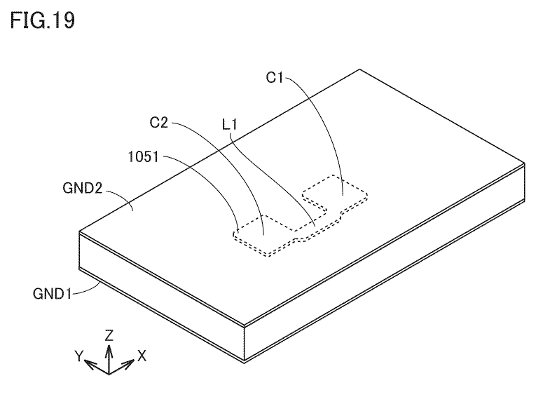

FIG. 19 is a perspective view illustrating filter device 105 included in antenna module 100H of the second embodiment. As illustrated in FIG. 19, for example, a resonator 1051 is formed of a substantially C-shaped plate electrode including regions C1, C2, L1. Substantially C-shaped resonator 1051 is disposed between a ground electrode GND1 and a ground electrode GND2. Regions C1, C2 function as a capacitor. Region L1 functions as an inductor. Thus, resonator 1051 functions as a filter.

“Resonator 1051” of the second embodiment corresponds to the “first electrode” of the present disclosure. “Ground electrode GND1” of the second embodiment corresponds to the “first ground electrode” of the present disclosure. “Ground electrode GND2” of the second embodiment corresponds to the “second ground electrode” of the present disclosure.

Returning to FIG. 18, a dielectric layer 160F8 and a dielectric layer 160G8 are filled with the plurality of fillers F. Dielectric layer 160F8 is disposed between ground electrode GND1 and resonator 1051. Dielectric layer 160G8 is disposed between ground electrode GND2 and resonator 1051.

In the filter included in the antenna module in which the plurality of dielectric layers is laminated as described above, when the effective permittivity between ground electrode GND1 and ground electrode GND2 is lowered, the areas of regions C1, C2 that function as the capacitors are required to increase in order to maintain the resonance frequency. Thus, the size of resonator 1051 can be increased.

In antenna module 100H of the second embodiment, as described above, the dielectric layer in which the plurality of fillers F is disposed is laminated between ground electrode GND1 and ground electrode GND2 and resonator 1051.

Thus, the effective permittivity between ground electrode GND2 and resonator 1051 can be reduced, and the size of resonator 1051 can be increased. Because the size of resonator 1051 is increased, the current density can be increased, and the characteristic of the filter is improved. In the antenna module 100H of the second embodiment, the layer not containing filler F may be further laminated between dielectric layer 160D8 and dielectric layer 160H8.

Filter device 105 of the second embodiment can be manufactured by a manufacturing process similar to the first and second manufacturing processes in FIGS. 13 to 16.

As described above, according to antenna module 100H of the second embodiment, antenna module 100H laminates the layer in which filler F is disposed in the region between ground electrode GND1 and ground electrode GND2 and resonator 1051 in filter device 105, so that the effective permittivity in the dielectric of the region can be reduced to improve the characteristic of filter device 105.

### Third Embodiment

In the second embodiment, the configuration in which the dielectric layer in which filler F is disposed is laminated in the region between ground electrode GND1 and ground electrode GND2 and resonator 1051, whereby the effective permittivity in the dielectric of the region is reduced to improve the characteristics of the filter has been described in the multilayer substrate on which the filter is formed.

The multilayer substrate used in the second embodiment can be used not only for the filter but also for the transmission line.

In a third embodiment, a configuration in which characteristic of the transmission line is improved by disposing filler F in the dielectric layer between a transmission electrode transmitting the high-frequency signal and a ground electrode will be described. The transmission electrode is a signal line transmitting the high-frequency signal.

Generally, when the effective permittivity between the transmission electrode such as a coaxial line, a strip line, or a microstrip line and the ground electrode is high, there arises a problem that the characteristic of the insertion loss in the transmission line is reduced.

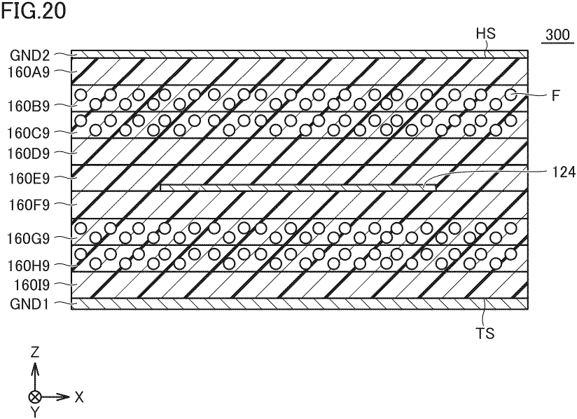

FIG. 20 is a sectional view illustrating a transmission line 300 of the third embodiment. Transmission line 300 in FIG. 20 is a transmission line in which a transmission electrode 124 transmitting the high-frequency signal is disposed between ground electrode GND1 and ground electrode GND2. That is, transmission line 300 is a strip line.

Transmission line 300 includes a dielectric layers 160A9 to 160I9. As illustrated in FIG. 20, the plurality of fillers F are disposed in dielectric layer 160B9 and dielectric layer 160C9 between ground electrode GND2 and transmission electrode 124. In addition, the plurality of fillers F are disposed in dielectric layer 160G9 and dielectric layer 160H9 between ground electrode GND1 and transmission electrode 124.

As a result, the effective permittivity between ground electrode GND2 and transmission electrode 124 and the effective permittivity between ground electrode GND1 and transmission electrode 124 are reduced, so that the characteristic of the insertion loss of the transmission line can be improved.

### Simulation Result

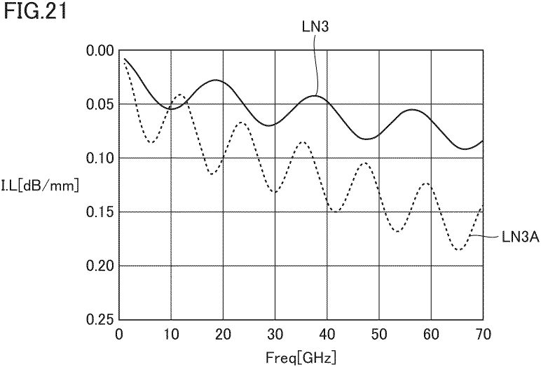

FIG. 21 is a simulation result in which the characteristic of transmission line 300 of the third embodiment and the transmission line having no filler F (comparative example) are compared. FIG. 21 illustrates the characteristic of the insertion loss in the transmission line.

A line LN3 is the characteristic of the insertion loss in transmission line 300 of the third embodiment. A line LN3A is the characteristic of the insertion loss in the transmission line (comparative example) having no filler F.

As described above, the frequency of transmission line 300 of the third embodiment can reduce the insertion loss of the transmission line over the wider band than the transmission line without filler F.

“Transmission electrode 124” of the third embodiment corresponds to the “first electrode” of the present disclosure. “Ground electrode GND1” and “ground electrode GND2” of the third embodiment correspond to “the “first ground electrode”” of the present disclosure. “Dielectric layer 160B9”, “dielectric layer 160C9”, “dielectric layer 160G9”, and “dielectric layer 160H9” of the third embodiment correspond to the “second layer” of the present disclosure. “Dielectric layer 160A9”, “dielectric layer 160D9”, “dielectric layer 160E9”, “dielectric layer 160F9”, and “dielectric layer 160I9” of the third embodiment correspond to the “first layer” of the present disclosure.

Transmission line 300 and a transmission line 300A of the third embodiment can be manufactured by a manufacturing process similar to the first and second manufacturing processes in FIGS. 13 to 16.

As described above, according to transmission line 300 of the third embodiment, in the transmission line such as the strip line, the layer in which filler F is disposed is laminated in the region between ground electrode GND1 and ground electrode GND2, and transmission electrode 124, so that the effective permittivity in the dielectric of the region can be reduced, and the characteristic of transmission line 300 can be improved.

### Modification of Third Embodiment

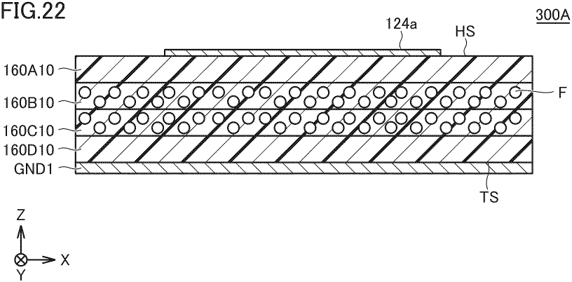

In a modification of the third embodiment, the transmission line that is a microstrip line will be described. FIG. 22 is a sectional view illustrating transmission line 300A according to a modification of the third embodiment.

Transmission line 300A includes a transmission electrode 124a and ground electrode GND1. Transmission electrode 124a is exposed. That is, transmission line 300A is the microstrip line.

In transmission line 300A, the plurality of fillers F are disposed between transmission electrode 124a and ground electrode GND1. As a result, the effective permittivity between transmission electrode 124a and ground electrode GND1 can be reduced. Therefore, as in FIG. 21, the insertion loss in transmission line 300A can be reduced.

It should be considered that the disclosed embodiments are an example in all respects and not restrictive. The scope of the present disclosure is defined by not the above description, but the claims, and it is intended that all modifications within the meaning and scope of the claims are included in the present disclosure.

### REFERENCE SIGNS LIST

10: communication device, 100, 100A, 100B, 100C, 100D, 100E, 100F, 100G, 100H, 100W: antenna module, 105: filter device, 105A, 105D: filter, 111A, 111D, 113A, 113D, 117: switch, 112AR, 112DR: low noise amplifier, 112AT, 112DT: power amplifier, 114A, 114D: attenuator, 115A, 115D: phase shifter, 116: splitter, 118: mixer, 119: amplifier circuit, 120: antenna array, 121: emission electrode, 121s: feed element, 122, 123: parasitic element, 124, 124a: transmission electrode, 140, 140W1, 140W2: feeder line, 160, 160W1, 160W2: dielectric substrate, 160A, 160B, 160C, 160E, 160F, 160G, 160H, 160I: dielectric layer, 300, 300A: transmission line, 1051: resonator, F: filler, GND, GND1, GND2: ground electrode, HS: first surface LN1, LN1A, LN3, LN3A: line, TS: second surface, 3S, 4S: surface, IM: intermediate member

1. A multilayer substrate, comprising:
a plurality of dielectric layers;
a first electrode disposed on the plurality of dielectric layers; and
a first ground electrode disposed on the plurality of dielectric layers and disposed so as to be opposite to the first electrode in a multilayer direction, wherein
the plurality of dielectric layers include a first layer and a second layer disposed between the first electrode and the first ground electrode,
a filler, having a permittivity lower than a permittivity of a base material of the plurality of dielectric layers, is disposed in the second layer and is not disposed in the first layer, and
in the second layer, the filler is disposed in at least a part of a region where the first electrode and the first ground electrode overlap each other in a planar view of the multilayer substrate from the multilayer direction.

2. The multilayer substrate according to claim 1, further comprising:
a first surface; and
a second surface opposite to the first surface in the multilayer direction, wherein
the plurality of dielectric layers further includes a third layer and a fourth layer,
the third layer includes the first surface and does not include the filler, and
the fourth layer includes the second surface and does not include the filler.

3. The multilayer substrate according to claim 1, further comprising:
a first substrate including the first electrode;
a second substrate including the first ground electrode; and
an intermediate member that electrically connects the first substrate and the second substrate, wherein
the second layer is disposed on at least one of the first substrate and the second substrate.

4. The multilayer substrate according to claim 1, wherein the filler has a hollow structure.

5. The multilayer substrate according to claim 1, wherein the base material contains a ceramic material.

6. The multilayer substrate according to claim 5, wherein the ceramic material is a low-temperature fired ceramic material.

7. An antenna module, comprising:
the multilayer substrate according to claim 1, wherein
the first electrode is an emission electrode that emits a radio wave,
the emission electrode includes a first emitter and a second emitter that are disposed in different layers and are opposite to each other, and
the second layer is disposed between the first emitter and the second emitter.

8. An antenna module, comprising:
the multilayer substrate according to claim 1, wherein
the first electrode is an emission electrode that emits a radio wave,
the emission electrode includes a first emitter and a second emitter that are disposed in different layers and are opposite to each other,
the plurality of dielectric layers further includes a third layer and a fourth layer that are disposed between the first emitter and the second emitter,
the fourth layer does not include the filler, and
the third layer includes the filler in at least a part of a region where the first emitter and the second emitter overlap each other in the planar view of the multilayer substrate from the multilayer direction.

9. A filter, comprising:
the multilayer substrate according to claim 1, wherein
the multilayer substrate further includes a second ground electrode,
the first electrode is disposed between the first ground electrode and the second ground electrode, and
the second layer is included in a layer between the first electrode and the first ground electrode and a layer between the first electrode and the second ground electrode.

10. A transmission line comprising the multilayer substrate according to claim 1, wherein the first electrode is a signal line that transmits a high-frequency signal.

11. A multilayer substrate, comprising:
a plurality of dielectric layers;
a first electrode disposed on the plurality of dielectric layers; and
a first ground electrode disposed on the plurality of dielectric layers and disposed so as to be opposite to the first electrode in a multilayer direction, wherein
the plurality of dielectric layers include a first specific region and a second specific region between the first electrode and the first ground electrode,
in a planar view of the multilayer substrate from the multilayer direction, the first electrode and the first ground electrode overlap each other in the first specific region and the first electrode and the first ground electrode do not overlap each other in the second specific region,
at least a part of the first specific region includes a filler having a permittivity lower than a permittivity of a base material of the plurality of dielectric layers, and
a permittivity of the first specific region is lower than a permittivity of the second specific region.

12. The multilayer substrate according to claim 11, wherein the base material of the plurality of dielectric layers contains a ceramic material.

13. An antenna module comprising the multilayer substrate according to claim 11, wherein the first electrode is an emission electrode that emits a radio wave.

14. The antenna module according to claim 13, wherein
the emission electrode includes a first emitter and a second emitter that are disposed in different layers and are opposite to each other, and
the first specific region is disposed between the first emitter and the second emitter.

15. The antenna module according to claim 13, wherein
the emission electrode includes a first emitter and a second emitter that are disposed in different layers and are opposite to each other,
the plurality of dielectric layers includes a third specific region and a fourth specific region between the first emitter and the second emitter,
in the planar view of the multilayer substrate from the multilayer direction, the first emitter and the second emitter overlap each other in the third specific region and the first emitter and the second emitter do not overlap each other in the fourth specific region,
at least a part of the third specific region includes the filler, and
a permittivity of the third specific region is lower than a permittivity of the fourth specific region.

16. A transmission line comprising the multilayer substrate according to claim 11, wherein the first electrode is a signal line that transmits a high-frequency signal.

17. A filter, comprising:
the multilayer substrate according to claim 11, wherein
the multilayer substrate further includes a second ground electrode, and
the first electrode is disposed between the first ground electrode and the second ground electrode.

18. The multilayer substrate according to claim 11, wherein the filler has a hollow structure.

19. The multilayer substrate according to claim 12, wherein the ceramic material is a low-temperature fired ceramic material.

20. A method for manufacturing a multilayer substrate, the method comprising:
disposing a first dielectric layer with a ground electrode;
disposing a second dielectric layer over the first dielectric layer;
forming a via in the second dielectric layer;
filling the via of the second dielectric layer with a filler; and
disposing, above the second dielectric layer, a third dielectric layer with a first electrode, wherein
the multilayer substrate includes a plurality of dielectric layers,
the plurality of dielectric layers includes the first dielectric layer, the second dielectric layer and the third dielectric layer, and
the filler has a permittivity lower than a permittivity of a base material of the plurality of dielectric layers.
